(19) United States
(12) Patent Application Publication
(10) Pub. No.: US 2023/0033295 A1
(43) Pub. Date: Feb. 2, 2023

(54) COMMUNICATION DEVICE, INDUSTRIAL MACHINE, AND COMMUNICATION METHOD

(71) Applicant: FANUC CORPORATION, Minamitsuru-gun (JP)

(72) Inventor: Takurou HAYASHI, Minamitsuru-gun, Yamanashi-ken (JP)

(21) Appl. No.: 17/788,709

(22) PCT Filed: Jan. 5, 2021
(86) PCT No.: PCT/JP2021/000043

§ 371 Date: Jun. 23, 2022

(30) Foreign Application Priority Data
Jan. 8, 2020 (JP) 2020-001323

(51) Int. Cl. H04L 7/033

(52) U.S. Cl. CPC H04L 7/033; H04L 2007/045

(57) ABSTRACT

Provided are a communication device, an industrial machine, and a communication method that contribute to accurate evaluation of communication quality. The present invention comprises: a reception unit that receives a serial signal; and a signal string acquisition unit that samples the serial signal at second periods that are shorter than a first period, which is a 1-bit period of the serial signal, thereby acquiring a signal string corresponding to 1 bit of the serial signal.

### TECHNICAL FIELD

The present invention relates to a communication device, an industrial machine, and a communication method.

### BACKGROUND ART

JP 2016-201687 A discloses a control system including a phase detection circuit and a phase determination circuit. The phase detection circuit detects a phase difference of serial data received by serial communication. The phase determination circuit determines whether or not the phase difference detected by the phase detection circuit has exceeded a preset threshold value, and then outputs a determination signal. When external noise is mixed into serial data under a noise environment, waveform distortion occurs in the serial data. When waveform distortion occurs in serial data, the phase detection circuit that has received the serial data detects a phase difference larger than in a normal state, and then outputs the phase difference as phase data.

### SUMMARY OF THE INVENTION

However, a technology that can contribute to a more accurate evaluation of the communication quality has been awaited.

An object of the present invention is to provide a communication device, an industrial machine, and a communication method that are capable of contributing to an accurate evaluation of the communication quality.

According to an aspect of the present invention, there is provided a communication device including: a reception unit configured to receive a serial signal; and a signal string acquisition unit configured to acquire a signal string corresponding to one bit of the serial signal by sampling the serial signal with a second period shorter than a first period which is a period of one bit of the serial signal.

An industrial machine according to another aspect of the present invention is equipped with the communication device as described above.

A communication method according to another aspect of the present invention includes: a reception step of receiving a serial signal; and a signal string acquisition step of acquiring a signal string corresponding to one bit of the serial signal by sampling the serial signal with a second period shorter than a first period which is a period of one bit of the serial signal.

According to the present invention, it is possible to provide the communication device, the industrial machine, and the communication method which are capable of contributing to an accurate evaluation of the communication quality.

### BRIEF DESCRIPTION OF DRAWINGS

FIG. 1 is a block diagram showing an industrial machine according to an embodiment;

FIG. 2 is a block diagram showing a communication device according to an embodiment;

FIG. 3 is a time chart showing an example of a serial signal and clock signals;

FIG. 4 is a time chart showing an example of sampling of a serial signal;

FIGS. 5A, 5B, and 5C are diagrams illustrating an example of a case where an inverted signal occurs;

FIG. 6 is a diagram illustrating an example of a case where an inverted signal occurs at the beginning or the ending of a signal string;

FIGS. 7A, 7B, and 7C are time charts showing an example of setting of the sampling period of a serial signal;

FIG. 8 is a flowchart showing an example of operations of a communication device according to an embodiment; and

FIG. 9 is a flowchart showing an example of operations of a communication device according to an embodiment.

### DESCRIPTION OF THE INVENTION

Hereinafter, a preferred embodiment of a communication device, an industrial machine, and a communication method according to the present invention will be described in detail with reference to the accompanying drawings.

### Embodiment

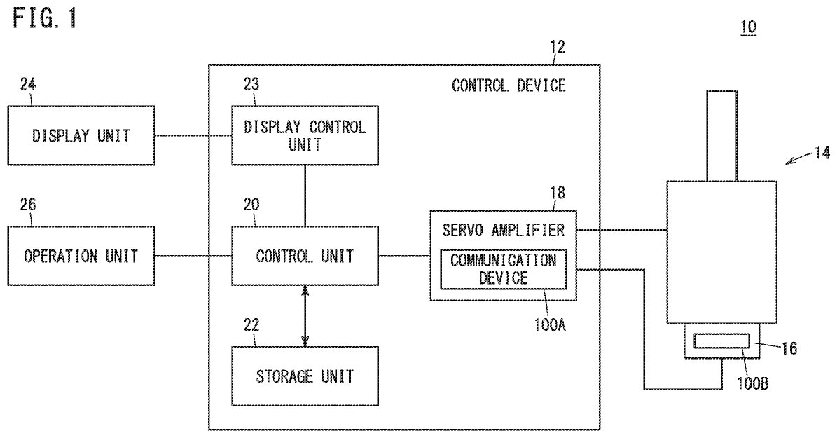

A communication device, an industrial machine, and a communication method according to an embodiment will be described with reference to FIGS. 1 to 9. FIG. 1 is a block diagram showing an industrial machine according to the present embodiment. As examples of such an industrial machine 10 according to the present embodiment, although not limited to such devices, there may be cited machine tools, robots, and the like.

As shown in FIG. 1, the industrial machine 10 is equipped with a control device 12. A servo amplifier 18, a control unit 20, a storage unit 22, and a display control unit 23 are provided in the control device 12. Moreover, although constituent elements other than these are provided in the control device 12, in order to simplify the description, constituent elements other than those components mentioned above will be omitted. Further, in this instance, although an exemplary case is described in which the servo amplifier 18 is provided in the industrial machine 10, the present invention is not necessarily limited to this feature. For example, in the case that a spindle motor is used as a drive motor, a spindle amplifier or the like may be used instead of the servo amplifier 18.

The control unit 20 controls the industrial machine 10 in its entirety. The control unit 20 may be configured, for example, by a CPU (Central Processing Unit) or the like, however, the control unit is not limited to this feature.

The storage unit 22 is equipped with a volatile memory and a nonvolatile memory, neither of which are shown. As examples of the volatile memory, there may be cited a RAM (Random Access Memory) or the like. As examples of the nonvolatile memory, there may be cited a ROM (Read Only Memory), a flash memory, or the like. Programs, data, and the like may be stored in the storage unit 22.

The display control unit 23 is capable of carrying out display control with respect to a later-described display unit 24. The display control unit 23 may display information supplied thereto from the control unit 20 on a display screen of the display unit 24.

The industrial machine 10 is further equipped with a servo motor 14. The servo motor 14 is capable of being driven by a drive current supplied from the servo amplifier 18. Although a single servo motor 14 is shown in FIG. 1, the industrial machine 10 may be equipped with a plurality of servo motors 14. Further, in this instance, although an exemplary case has been described in which the servo motor 14 is provided as a drive motor in the industrial machine 10, the present invention is not necessarily limited to this feature. For example, a spindle motor or the like may be used instead of the servo motor 14.

An encoder (absolute encoder) 16 is provided in the servo motor 14. The encoder 16 is capable of detecting a rotational position of the output shaft of the servo motor 14. The encoder 16 is equipped with a communication device 100B that serves to carry out communications with a communication device 100A that is provided in the servo amplifier 18. The communication device 100B is capable of outputting a signal to indicate the rotational position of the output shaft of the servo motor 14, to the communication device 100A. The servo motor 14 may be feedback controlled based on signals that are output from the encoder 16, i.e., based on signals that are output from the communication device 100B. Further, in this instance, although an exemplary case is described in which an absolute encoder is used as the encoder 16, the present invention is not necessarily limited to this feature. For example, an incremental encoder may also be used as the encoder 16.

The servo amplifier (servo driver) 18 may supply a drive current for rotationally driving the servo motor 14, to the servo motor 14. The communication device 100A, which carries out communications with the communication device 100B, is provided in the servo amplifier 18. Serial communications may be carried out between the communication device 100A and the communication device 100B. Although, as an example of such a serial communication standard, there may be cited RS-485 or the like, the present invention is not necessarily limited to this feature.

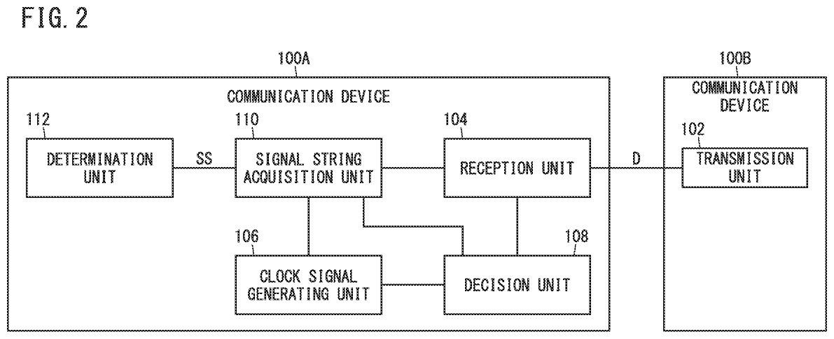

The display unit (display device) 24, and an operation unit 26 may be connected to the control device 12. An operation screen in order to perform inputting of operations with respect to the industrial machine 10 may be displayed on a non-illustrated display screen provided in the display unit 24. In addition, information acquired by a signal string acquisition unit 110 (see FIG. 2) described later may be displayed on the display screen of the display unit 24. Further, on the display screen of the display unit 24, there may be displayed information indicating determination results made by a later-described determination unit 112 (see FIG. 2). A liquid crystal display device or the like can be used as the display unit 24, however, the display unit 24 is not limited to this feature.

The user is capable of inputting operations with respect to the industrial machine 10 by operating the operation unit 26. As the operation unit 26, there may be used a mouse or the like, although the present invention is not limited to this feature. In the case that the display unit 24 is provided with a touch panel, such a touch panel is capable of functioning as the operation unit 26.

Moreover, although constituent elements other than those described above are provided in the industrial machine 10, in order to simplify the description, constituent elements other than those components mentioned above will be omitted.

FIG. 2 is a block diagram showing a communication device according to the present embodiment.

As described above, the communication device 100A is provided in the servo amplifier 18. As described above, the communication device 100B is provided in the encoder 16. Moreover, in this instance, although an exemplary case is described in which the communication device 100A is provided in the servo amplifier 18, and the communication device 100B is provided in the encoder 16, the present invention is not necessarily limited to this feature.

The communication device 100B includes a transmission unit (transmission circuit) 102. Although constituent elements other than the transmission unit 102 are provided in the communication device 100B, in order to simplify the description, constituent elements other than the transmission unit 102 will be omitted in FIG. 2.

The communication device 100A includes a reception unit (receiving circuit, transceiver) 104. The reception unit 104 can receive a serial signal D, i.e., serial data, transmitted from the transmission unit 102.

The communication device 100A is further equipped with a clock signal generating unit (clock signal generating circuit) 106.

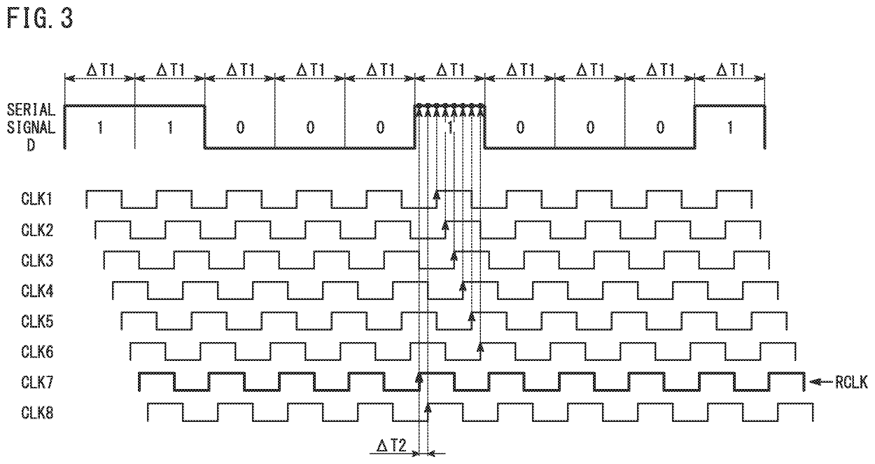

FIG. 3 is a time chart showing an example of a serial signal and clock signals. As shown in FIG. 3, the clock signal generating unit 106 is capable of generating a plurality of clock signals CLK1 to CLK8 that have mutually different phases. The clock signal CLK1 can be generated by using, for example, a non-illustrated crystal oscillator. The clock signals (phase shifted clock signals) CLK2 to CLK8 can be generated from the clock signal CLK1 using, for example, a non-illustrated phase shift circuit (clock phase shift circuit). When the clock signals are described in general, the reference numeral CLK is used, and when individual ones of the clock signals are described, the reference numerals CLK1 to CLK8 are used. In this instance, although an exemplary case is described in which eight of the clock signals CLK are generated by the clock signal generating unit 106, the number of the clock signals CLK generated by the clock signal generating unit 106 is not limited to eight.

The clock signal CLK may be used to sample the serial signal D. Here, a case where the serial signal D is sampled at the rising timing of the clock signal CLK will be described as an example, but the present invention is not limited thereto. The serial signal D may be sampled at the falling timing of the clock signal CLK. The periods of the plurality of clock signals CLK are equal to each other. The plurality of clock signals CLK are not synchronized with the serial signal D supplied from the transmission unit 102. The period of the clock signal CLK may be set to be equal to the first period ΔT1, which is the period of one bit of the serial signal D, for example, but is not limited thereto. Here, a case where the period of the clock signal CLK is set to be equal to the first period ΔT1 which is the period of one bit of the serial signal D will be described as an example.

The sampling period of the serial signal D is set to a second period ΔT2 shorter than the first period ΔT1 which is the period of one bit of the serial signal D. The first period ΔT1 is an integral multiple of the second period ΔT2. Here, a case where the first period ΔT1 is eight times the second period ΔT2 will be described as an example. The rising timings of the plurality of clock signals CLK are shifted by the second period ΔT2. The clock signals CLK have phase differences corresponding to the second period ΔT2.

A decision unit (decision circuit) 108 is further provided in the communication device 100A. The decision unit 108, the later-described signal string acquisition unit 110, and the later-described determination unit 112 may be configured by one or more processors (microprocessors), however, the present invention is not limited to this feature. As such processors, for example, a CPU, a DSP (Digital Signal Processor), or the like can be used. The decision unit 108 decides, as a reference clock signal RCLK, a clock signal CLK that is located immediately after the edge of the serial signal D, among the plurality of clock signals CLK. The reference clock signal RCLK serves as a trigger for sampling a portion corresponding to one bit of the serial signal D. As described above, the plurality of clock signals CLK generated by the clock signal generating unit 106 are out of phase with each other and are not synchronized with the serial signal D. In order to accurately sample the portion corresponding to one bit of the serial signal D, the decision unit 108 decides the clock signal CLK located immediately after the edge of the serial signal D, as the reference clock signal RCLK. In the example shown in FIG. 3, the clock signal CLK, which is positioned immediately after the rising edge of the serial signal D, is the clock signal CLK7. In the example shown in FIG. 3, the clock signal CLK7 is decided as the reference clock signal RCLK.

The clock signal CLK positioned immediately after the edge of the serial signal D may fluctuate due to jitter or the like. Accordingly, when the reference clock signal RCLK is decided, it is preferable to decide, as the reference clock signal RCLK, a clock signal CLK whose frequency of occurrence of signal positioned immediately after the edge of the serial signal D is sufficiently high, more specifically, a clock signal CLK that has the frequency of occurrence of the signal being greater than or equal to a frequency threshold value. The frequency threshold value can be, for example, on the order of 80%, but is not limited to this feature. For example, the clock signal CLK positioned immediately after an nth edge of the serial signal D is the clock signal CLK7. The clock signal CLK positioned immediately after an (n+1)th edge of the serial signal D is the clock signal CLK7. The clock signal CLK positioned immediately after an (n+2)th edge of the serial signal D is the clock signal CLK8. The clock signal CLK positioned immediately after an (n+3)th edge of the serial signal D is the clock signal CLK7. The clock signal CLK positioned immediately after an (n+4)th edge of the serial signal D is the clock signal CLK7. In the case that the frequency threshold value is 80%, the clock signal CLK that has the frequency of occurrence being equal to or greater than the frequency threshold value is the clock signal CLK7. In this case, the decision unit 108 may decide the clock signal CLK7 as the reference clock signal RCLK.

Moreover, as noted previously, although an exemplary case is described in which a clock signal CLK whose frequency of occurrence of signal positioned immediately after the edge of the serial signal D is greater than or equal to the frequency threshold value is decided as being the reference clock signal RCLK, the present invention is not necessarily limited to this feature. A clock signal CLK whose frequency of occurrence of signal occurring immediately after the edge of the serial signal D is the highest may be decided as being the reference clock signal RCLK.

As noted previously, the period of the clock signals CLK is set to be equivalent to the first period ΔTI, which is the period of one bit of the serial signal D. Therefore, it is not necessary to frequently change the reference clock signal RCLK. However, a slight error may occur between the period of the clock signal CLK and the period of one bit of the serial signal D. Therefore, there are cases in which another clock signal CLK, which differs from the clock signal CLK that was previously decided as being the reference clock signal RCLK, may occur immediately after the edge of the serial signal D. In such a case, the decision unit 108 newly decides the other clock signal CLK, which has become positioned immediately after the edge of the serial signal D, as being the reference clock signal RCLK. Such a change of the reference clock signal RCLK may occur at a certain frequency.

The communication device 100A further includes a signal string acquisition unit (signal string acquisition circuit) 110. The signal string acquisition unit 110 acquires a signal string SS corresponding to one bit of the serial signal D by sampling the serial signal D with the second period ΔT2 based on the plurality of clock signals CLK. That is, the signal string acquisition unit 110 samples the serial signal D based on the plurality of clock signals CLK using the reference clock signal RCLK as a trigger.

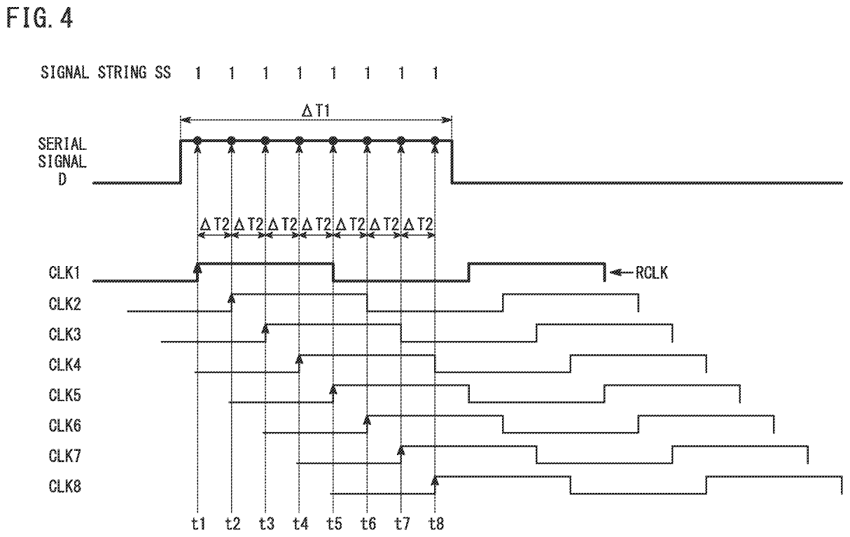

FIG. 4 is a time chart showing an example of sampling of a serial signal. In the example shown in FIG. 4, a clock signal CLK that is positioned immediately after the rising edge of the serial signal D, is the clock signal CLK1. Therefore, in the example shown in FIG. 4, the clock signal CLK1 is decided as the reference clock signal RCLK. In the example illustrated in FIG. 4, the signal string acquisition unit 110 samples the serial signal D using the reference clock signal RCLK, i.e., the clock signal CLK1, as a trigger. That is, the signal string acquisition unit 110 samples the serial signal D at the rising timing t1 of the clock signal CLK1. A signal obtained by sampling the serial signal D with the reference clock signal RCLK is the beginning signal of the signal string SS. After that, the signal string acquisition unit 110 samples the serial signal D at each of the rising timings t2, t3, t4, t5, t6, t7, and t8 of the respective clock signals CLK2, CLK3, CLK4, CLK5, CLK6, CLK7, and CLK8. In the example illustrated in FIG. 4, the serial signal D is at a high level (H), i.e., “1”, at all of the timings t1, t2, t3, t4, t5, t6, t7, and t8. In this manner, the signal string SS corresponding to one bit of the serial signal D is acquired by the signal string acquisition unit 110. In the example illustrated in FIG. 4, the signal string SS acquired by the signal string acquisition unit 110 is “11111111”.

The signal string acquisition unit 110 repeatedly performs such processing on each of the plurality of bits constituting the serial signal D. In this manner, the signal string SS corresponding to each of the plurality of bits constituting the serial signal D is sequentially acquired. The signal string acquisition unit 110 can supply the signal string SS acquired in this manner to the determination unit 112. In addition, the signal string acquisition unit 110 can supply the signal string SS acquired in this manner to the control unit 20.

The determination unit (determination circuit) 112 is further provided in the communication device 100A. The determination unit 112 determines the serial signal D corresponding to the signal string SS, i.e., 1-bit information of the serial signal D, based on signals that form a majority (the largest or larger group) of the plurality of signals included in the signal string SS. For example, the determination unit 112 may determine the serial signal D corresponding to the signal string SS, based on signals that form a majority of the plurality of signals included in the signal string SS. For example, when the number of signals included in the signal string SS is eight and the number of signals indicating “1” is five or more, the signals of “1” form the majority. In such a case, the determination unit 112 determines that the serial signal D corresponding to the signal string SS is “1”. In addition, in a case where the number of signals included in the signal string SS is eight and the number of signals indicating “0” is five or more, the signals of “0” form the majority. In such a case, the determination unit 112 determines that the serial signal D corresponding to the signal string SS is “0”.

The determination unit 112 can count the number of inverted signals. The inverted signal is a signal that is inverted with respect to signals that form the majority of the plurality of signals included in the signal string SS. In the example illustrated in FIG. 4, signals that form the majority of the plurality of signals included in the signal string SS, are of “1”. Thus, the inverted signal, which is inverted with respect to the signal of “1”, which belongs to the majority, is of “0”. In the example illustrated in FIG. 4, the determination unit 112 determines that the number of inverted signals is 0. The determination unit 112 can supply the number of inverted signals determined in this manner to the control unit 20.

The determination unit 112 may count the number of consecutive occurrences of the inverted signal. In the example illustrated in FIG. 4, the determination unit 112 determines that the number of consecutive occurrences of the inverted signal is 0. The determination unit 112 can supply the number of consecutive occurrences of the inverted signal determined in this manner to the control unit 20.

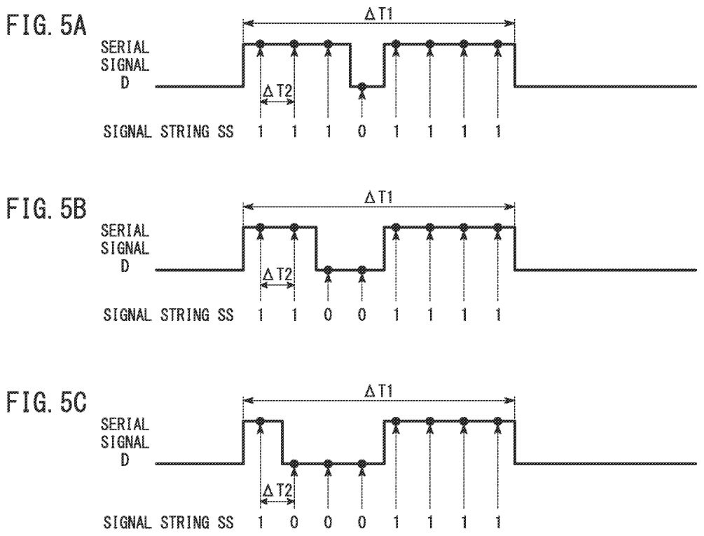

FIGS. 5A to 5C are diagrams illustrating an example of a case where an inverted signal occurs. FIG. 5A corresponds to a case where the influence of noise is relatively small, or a case where the frequency of noise is relatively high. FIG. 5B corresponds to a case where the influence of noise is medium or a case where the frequency of noise is medium. FIG. 5C corresponds to a case where the influence of noise is relatively large or a case where the frequency of noise is relatively low.

In the example illustrated in FIG. 5A, the signal string SS acquired by the signal string acquisition unit 110 is of “11101111”. In such a case, the determination unit 112 determines that the number of inverted signals is one, and determines that the number of consecutive occurrences of inverted signals is one.

In the example illustrated in FIG. 5B, the signal string SS acquired by the signal string acquisition unit 110 is of “11001111”. In such a case, the determination unit 112 determines that the number of inverted signals is two, and determines that the number of consecutive occurrences of inverted signals is two.

In the example illustrated in FIG. 5C, the signal string SS acquired by the signal string acquisition unit 110 is of “10001111”. In such a case, the determination unit 112 determines that the number of inverted signals is three, and determines that the number of consecutive occurrences of inverted signals is three.

In a case where the length of the transmission path between the communication device 100A and the communication device 100B is relatively long, the waveform of the serial signal D may become dulled or lose shape. In a case where the waveform of the serial signal D becomes dulled, an inverted signal may occur at the beginning or the ending of the signal string SS acquired by the signal string acquisition unit 110. In addition, when the waveform of the serial signal D becomes dulled to a relatively large extent, not only an inverted signal occurs at the beginning of the signal string SS acquired by the signal string acquisition unit 110 but also another inverted signal may occur so as to be continuous with the beginning inverted signal. In addition, when the waveform of the serial signal D becomes dulled to a relatively large extent, an inverted signal may occur not only at the ending of the signal string SS acquired by the signal string acquisition unit 110 but also another inverted signal may occur so as to be continuous with the ending inverted signal. The determination unit 112 counts the number of inverted signals while excluding the inverted signal at the beginning or the ending of the signal string SS and the inverted signal continuous with the inverted signal at the beginning or the ending of the signal string SS. That is, the determination unit 112 counts the inverted signals caused by noise, as the number of inverted signals, but does not count the inverted signals caused by the dulled waveform of the serial signal D, as the number of inverted signals.

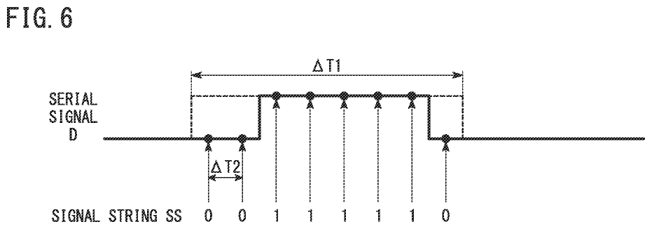

FIG. 6 is a diagram illustrating an example of a case where an inverted signal occurs at the beginning or the ending of a signal string. In the example illustrated in FIG. 6, not only an inverted signal occurs at the beginning of the signal string SS acquired by the signal string acquisition unit 110, but also another inverted signal occurs continuously with the beginning inverted signal. Further, in the example illustrated in FIG. 6, an inverted signal also occurs at the ending of the signal string SS acquired by the signal string acquisition unit 110.

In the example illustrated in FIG. 6, the determination unit 112 counts the number of inverted signals with the inverted signal positioned at the beginning of the signal string SS acquired by the signal string acquisition unit 110 being excluded. Further, in the example illustrated in FIG. 6, the determination unit 112 counts the number of inverted signals with the inverted signal continuous with the inverted signal positioned at the beginning of the signal string SS acquired by the signal string acquisition unit 110, i.e., the inverted signal located at the second position in the signal string SS being excluded. Further, in the example illustrated in FIG. 6, the determination unit 112 counts the number of inverted signals with the inverted signal positioned at the ending of the signal string SS acquired by the signal string acquisition unit 110 being excluded. Therefore, in the example illustrated in FIG. 6, the determination unit 112 determines that the number of inverted signals is 0. As described above, the determination unit 112 does not count inverted signals generated due to the dulled waveform of the serial signal D, as the number of inverted signals.

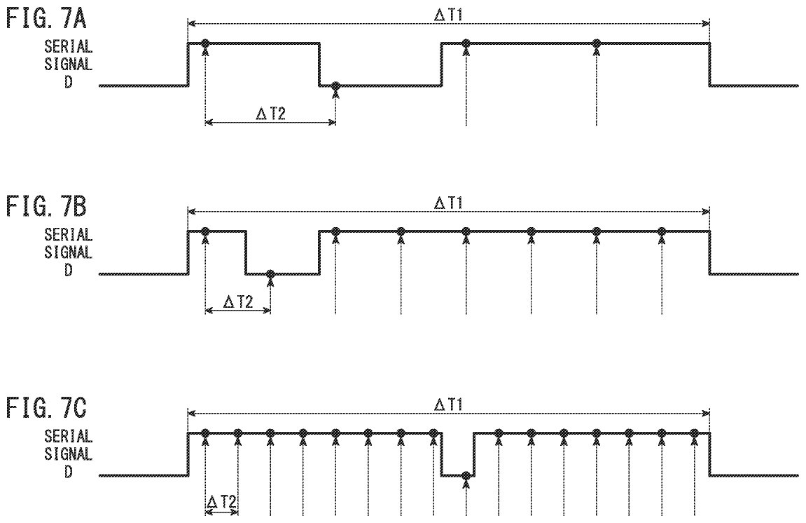

The sampling period of the serial signal D, i.e., the second period ΔT2, is variable. FIGS. 7A to 7C are time charts showing an example of setting of the sampling period of the serial signal. FIG. 7A shows an example in which the sampling period ΔT2 of the serial signal D is set to be relatively large. FIG. 7B shows an example in which the sampling period ΔT2 of the serial signal D is set to an intermediate level. FIG. 7C shows an example in which the sampling period ΔT2 of the serial signal D is set to be relatively small.

As shown in FIG. 7C, in a case where the duration in which the serial signal D remains inverted is relatively short, i.e., when the number of consecutive occurrences of the inverted signal is relatively small, the sampling period ΔT2 of the serial signal D must be set to be relatively small in order to detect the inverted signal satisfactorily. Therefore, when the duration of inversion of the serial signal D is relatively short, it is necessary to set the sampling period ΔT2 of the serial signal D to be relatively small.

As shown in FIG. 7B, in a case where the duration in which the serial signal D remains inverted is medium, i.e., when the number of consecutive occurrences of the inverted signal is medium, even if the sampling period ΔT2 of the serial signal D is set to be medium, the inverted signal can be favorably detected. Therefore, in the case where the duration of inversion of the serial signal D is medium, the sampling period ΔT2 of the serial signal D may be set to medium. Increasing the sampling period ΔT2 of the serial signal D can contribute to a reduction in processing load, a reduction in power consumption, and the like.

As shown in FIG. 7A, in a case where the duration in which the serial signal D remains inverted is relatively long, i.e., when the number of consecutive occurrences of the inverted signal is relatively large, the inverted signal can be satisfactorily detected even if the sampling period ΔT2 of the serial signal D is set to be relatively large. Therefore, when the duration of inversion of the serial signal D is relatively large, the sampling period ΔT2 of the serial signal D may be set to be relatively large. As described above, increasing the sampling period ΔT2 of the serial signal D can contribute to reduction in processing load, reduction in power consumption, and the like.

The user can adjust the sampling period of the serial signal D based on information displayed on the display screen of the display unit 24. For example, the display screen of the display unit 24 may display the signal string SS acquired by the signal string acquisition unit 110, the number of inverted signals determined by the determination unit 112, the number of consecutive occurrences of inverted signals determined by the determination unit 112, and the like. Based on these pieces of information displayed on the display unit 24, the user can grasp the magnitude of the influence of noise, the noise frequency, the frequency of occurrence of noise, and the like. In the case where the number of consecutive occurrences of the inverted signal is relatively small, the user can set the sampling period of the serial signal D to be relatively small, as illustrated in FIG. 7C. In the case where the number of consecutive occurrences of the inverted signal is medium, the user can set the sampling period of the serial signal D to be medium, as illustrated in FIG. 7B. In the case where the number of consecutive occurrences of the inverted signal is relatively large, the user can set the sampling period of the serial signal D to be relatively large, as shown in FIG. 7A.

The user can also change the route of the transmission path between the communication device 100A and the communication device 100B based on the information displayed on the display screen of the display unit 24. For example, as illustrated in FIG. 7A, in a case where the number of consecutive occurrences of the inverted signal is relatively large, the user may recognize that the influence of noise may be relatively large. In such a case, the user may change the route of the transmission path between the communication device 100A and the communication device 100B. By appropriately changing the route of the transmission path between the communication device 100A and the communication device 100B, the transmission path can be disposed at a location that is less susceptible to noise.

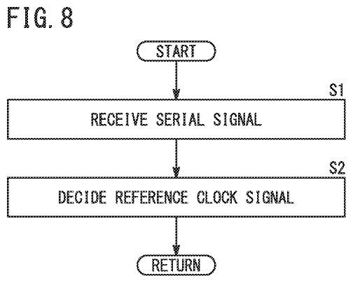

A description will be given below with reference to FIG. 8 concerning an example of operations of the communication device according to the present embodiment. FIG. 8 is a flowchart showing an example of operations of the communication device according to the present embodiment. Operations in order to decide the reference clock signal RCLK are shown in FIG. 8.

In step S1, the reception unit 104 receives the serial signal D. Thereafter, the process transitions to step S2.

In step S2, the decision unit 108 decides, as a reference clock signal RCLK, a clock signal CLK that is located immediately after the edge of the serial signal D, among the plurality of clock signals CLK. Although a clock signal CLK whose frequency of occurrence of signal occurring immediately after the edge of the serial signal D is greater than or equal to the frequency threshold value, can be decided as being the reference clock signal RCLK, the present invention is not necessarily limited to this feature. A clock signal CLK whose frequency of occurrence of signal occurring immediately after the edge of the serial signal D is the highest may be decided as being the reference clock signal RCLK.

In this manner, the process shown in FIG. 8 is brought to an end.

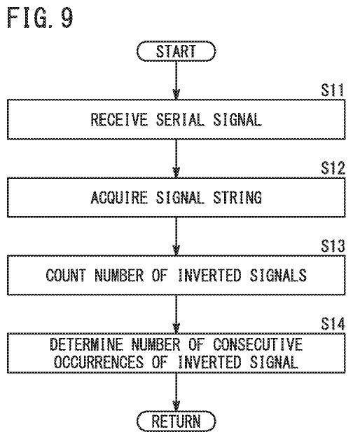

A description will be given below with reference to FIG. 9 concerning an example of operations of the communication device according to the present embodiment. FIG. 9 is a flowchart showing an example of operations of the communication device according to the present embodiment. FIG. 9 shows operations such as acquisition of a signal string.

In step S11, the reception unit 104 receives the serial signal D. Thereafter, the process transitions to step S12.

In step S12, the signal string acquisition unit 110 samples the serial signal D based on the plurality of clock signals CLK using the reference clock signal RCLK as a trigger. Thus, a signal string SS corresponding to one bit of the serial signal D is acquired. Thereafter, the process transitions to step S13.

In step S13, the determination unit 112 counts the number of inverted signals in the signal string SS acquired by the signal string acquisition unit 110. Thereafter, the process transitions to step S14.

In step S14, the determination unit 112 determines the number of consecutive occurrences of the inverted signal in the signal string SS acquired by the signal string acquisition unit 110.

In this manner, the process shown in FIG. 9 is brought to an end.

As described above, according to the present embodiment, the serial signal D is sampled at the second period ΔT2 shorter than the first period ΔT1, which is the period of one bit of the serial signal D, to thereby acquire the signal string SS corresponding to one bit of the serial signal D. Based on the signal string SS, it is possible to grasp how the inverted signals occur, the number of inverted signals, the number of consecutive occurrences of the inverted signal, and the like. Thus, according to the present embodiment, it is possible to contribute to accurate evaluation of communication quality.

Although a preferred embodiment of the present invention have been described above, the present invention is not limited to the above-described embodiment, and various modifications can be made thereto within a range that does not depart from the essence and gist of the present invention.

Moreover, in this instance, although an exemplary case is described in which the communication device 100A is provided in the servo amplifier 18, and the communication device 100B is provided in the encoder 16, the present invention is not necessarily limited to this feature. The communication devices 100A and 100B may be included in various devices.

The above-described embodiment can be summarized in the following manner.

The communication device (100A) includes: a reception unit (104) configured to receive a serial signal (D); and a signal string acquisition unit (110) configured to acquire a signal string (SS) corresponding to one bit of the serial signal by sampling the serial signal with a second period (ΔT2) shorter than a first period (ΔT1) which is the period of one bit of the serial signal. With such a configuration, since it is possible to acquire a signal string corresponding to one bit of the serial signal, it is possible to grasp how the inverted signal occurs, the number of inverted signals, the number of consecutive occurrences of the inverted signal, and the like, based on the signal string. In accordance with such a configuration, it is possible to contribute to an accurate evaluation of the communication quality.

The communication device may further include a determination unit (112) configured to count the number of inverted signals that are inverted with respect to signals that form a majority of a plurality of signals included in the signal string. With such a configuration, it is possible to easily grasp the number of inverted signals.

The determination unit may count the number of inverted signals while excluding an inverted signal at the beginning or the ending of the signal string and an inverted signal continuous with the inverted signal at the beginning or the ending of the signal string. With such a configuration, it is possible to exclude an influence caused by the dulled waveform of the serial signal, etc., and to contribute to more accurate evaluation of the communication quality.

The determination unit may further count the number of consecutive occurrences of the inverted signal. With such a configuration, it is possible to grasp the magnitude of the influence of noise, the noise frequency, and the like.

The communication device may further include a clock signal generating unit (106) configured to generate a plurality of clock signals (CLK1 to CLK8) each having a phase difference corresponding to the second period, periods of the plurality of clock signals being equal to each other; and a decision unit (108) configured to decide, as a reference clock signal (RCLK), a clock signal located immediately after an edge of the serial signal, among the plurality of clock signals, wherein the signal string acquisition unit may sample the serial signal based on the plurality of clock signals, using the reference clock signal as a trigger.

The first period (ΔT1) may be an integral multiple of the second period (ΔT2).

The second period may be variable. With this configuration, the second period can be appropriately set in accordance with the length of the duration in which the serial signal remains inverted. By setting the second period to be relatively large, it is possible to contribute to reduction of processing impossibility, reduction of power consumption, and the like.

The industrial machine (10) is equipped with the communication device as described above.

The communication method includes: a reception step (S11) of receiving a serial signal; and a signal string acquisition step (S12) of acquiring a signal string corresponding to one bit of the serial signal by sampling the serial signal with a second period shorter than a first period which is a period of one bit of the serial signal.

The method may further include a step (S13) of counting the number of inverted signals that are inverted with respect to signals that form a majority of a plurality of signals included in the signal string.

In the step of counting the number of determination signals, the number of inverted signals may be counted while excluding an inverted signal at the beginning or the ending of the signal string and an inverted signal continuous with the inverted signal at the beginning or the ending of the signal string.

The method may further include a step (S14) of determining the number of consecutive occurrences of the inverted signal.

The method may further include a decision step (S2) of deciding, as a reference clock signal, a clock signal located immediately after an edge of the serial signal, among a plurality of clock signals each having a phase difference corresponding to the second period, the periods of the plurality of clock signals being equal to each other, wherein in the signal string acquisition step, the serial signal may be sampled based on the plurality of clock signals, using the reference clock signal as a trigger.

1. A communication device comprising:
a reception unit configured to receive a serial signal; and
a signal string acquisition unit configured to acquire a signal string corresponding to one bit of the serial signal by sampling the serial signal with a second period shorter than a first period which is a period of one bit of the serial signal.

2. The communication device according to claim 1, further comprising:
a determination unit configured to count a number of inverted signals that are inverted with respect to signals that form a majority of a plurality of signals included in the signal string.

3. The communication device according to claim 2, wherein
the determination unit counts the number of the inverted signals while excluding an inverted signal at a beginning or an ending of the signal string and an inverted signal continuous with the inverted signal at the beginning or the ending of the signal string.

4. The communication device according to claim 2, wherein
the determination unit further counts a number of consecutive occurrences of the inverted signal.

5. The communication device according to claim 1, further comprising:
a clock signal generating unit configured to generate a plurality of clock signals each having a phase difference corresponding to the second period, periods of the plurality of clock signals being equal to each other; and
a decision unit configured to decide, as a reference clock signal, a clock signal located immediately after an edge of the serial signal, among the plurality of clock signals,
wherein the signal string acquisition unit samples the serial signal based on the plurality of clock signals, using the reference clock signal as a trigger.

6. The communication device according to claim 1, wherein
the first period is an integral multiple of the second period.

7. The communication device according to claim 1, wherein
the second period is variable.

8. An industrial machine comprising the communication device according to claim 1.

9. A communication method comprising:
a reception step of receiving a serial signal; and
a signal string acquisition step of acquiring a signal string corresponding to one bit of the serial signal by sampling the serial signal with a second period shorter than a first period which is a period of one bit of the serial signal.

10. The communication method according to claim 9, further comprising:
a step of counting a number of inverted signals that are inverted with respect to signals that form a majority of a plurality of signals included in the signal string.

11. The communication method according to claim 10, wherein
in the step of counting the number of the inverted signals, the number of the inverted signals is counted while excluding an inverted signal at a beginning or an ending of the signal string and an inverted signal continuous with the inverted signal at the beginning or the ending of the signal string.

12. The communication method according to claim 10, further comprising:
a step of determining a number of consecutive occurrences of the inverted signal.

13. The communication method according to claim 9, further comprising:
a decision step of deciding, as a reference clock signal, a clock signal located immediately after an edge of the serial signal, among a plurality of clock signals each having a phase difference corresponding to the second period, periods of the plurality of clock signals being equal to each other,
wherein in the signal string acquisition step, the serial signal is sampled based on the plurality of clock signals, using the reference clock signal as a trigger.
